(19) United States
(12) Patent Application Publication
(10) Pub. No.: US 2009/0085216 A1
(43) Pub. Date: Apr. 2, 2009

(54) Semiconductor device

(75) Inventors: Yasuo Tanaka, Tokyo (JP); Yoshifumi Sakamoto, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/219,301

(22) Filed: Jul. 18, 2008

(30) Foreign Application Priority Data
Aug. 27, 2007 (JP) 2007-219972

(51) Int. Cl. H01L 23/48

(52) U.S. Cl. 257/772; 257/E23.01

(57) ABSTRACT

The present invention provides a semiconductor device excellent in the reliability of connection between the semiconductor device and a mounting board. The semiconductor device has external connecting terminals. Each of the external connecting terminals includes a Cu electrode, intermetallic compounds containing Cu, each formed over the Cu electrode, stopper portions which cover surfaces of the intermetallic compounds at intervals, and a solder alloy comprising Bi and an impurity containing Sn formed over the stopper portions and the intermetallic compounds.

### BACKGROUND OF THE INVENTION

The present invention relates to a semiconductor device, and particularly to a semiconductor device having a plurality of solder terminals at a connection surface.

With the lightness, thinness, shortness and smallness of recent electronic equipment and their higher performance, there have been demands for miniaturization and high functionality of electronic components used in these electronic equipment.

In order to meet these demands, there has been proposed a semiconductor device of a so-called CSP (Chip Size Package) structure wherein the shape of the semiconductor device is brought as close to a chip shape of an LSI (Large Scale Integrated Circuit) as possible thereby to provide miniaturization.

Of these, a wafer level CSP has been realized which uses a technique for bringing a semiconductor chip into package form while a wafer state is held as it is, in terms of a reduction in manufacturing cost and an improvement in productivity.

In order to adapt to such a miniaturized semiconductor device of wafer level CSP structure, alloy composition excellent in ductility, thermal fatigue strength and corrosion resistance or the like has been proposed as for solder used to connect between a printed circuit board or mounting board and its corresponding semiconductor device (refer to, for example, a patent document 1 (Japanese Unexamined Patent Publication No. Hei 11(1999)-221693)).

Even though, however, the solder having such alloy composition is used in the junction between the mounting board and the semiconductor device, a large mismatch occurs and substrate connection reliability is low for such reasons as a hard material thereof, etc. There is an increasingly trend to reduce a terminal diameter from now on, and the substrate connection reliability is further deteriorated.

The cause of the deterioration in the substrate connection reliability resides in that as shown in FIGS. 9(A) through 9(C), a layer composed of an intermetallic compound 920 having a large number of protrusions ununiform in height and shape is formed at an interface 908 between a Cu electrode 906 and an external connecting terminal 910. This is one formed by allowing Cu of the Cu electrode 906 and Sn in solder composition to be solid-soluble to each other. This layer changes with time and thereby a Cu3Sn layer and a Cu6Sn5 layer are sequentially formed from the Cu electrode 906 side to the external connecting terminal 910 side. The thicknesses of these exceed 10 μm in total. In doing so, stress concentrates locally due to volumetric expansion and shrinkage caused by the difference in density between Cu, Cu3Sn and Cu6Sn5, thereby causing cracks.

Thus, when the conventional solder is used in spots being placed under hostile use environments, sufficient connection reliability is not obtained and hence this has been reinforced by underfill, for example.

### SUMMARY OF THE INVENTION

The present invention has been made in view of the foregoing problems and aims to attain the following object.

Namely, an object of the present invention is to provide a semiconductor device excellent in the reliability of connection between the semiconductor device and a mounting board.

The present inventors have carried out extensive or keen investigations in view of the above. As a result, the present inventors have found out that the problem related to the connection reliability can be solved by using the following semiconductor device. This has led to the attainment of the above object.

According to a first aspect of the present invention, there is provided a semiconductor device comprising external connecting terminals, wherein each of the external connecting terminals includes a Cu electrode, intermetallic compounds containing Cu, each formed over the Cu electrode, stopper portions which cover surfaces of the intermetallic compounds at intervals, and a solder alloy comprising Bi and an impurity containing Sn formed over the stopper portions and the intermetallic compounds.

According to the above semiconductor device, since the stopper portion containing Bi surrounds each intermetallic compound, the area at which the intermetallic compound and Sn in the composition of solder contact each other, is reduced. In doing so, the growth of the intermetallic compound that was the cause of deteriorating the connection reliability, can be inhibited. When the generation of these intermetallic compounds is suppressed, it is possible to relax the generation of local stress caused by volumetric expansion or volumetric shrinkage due to the difference in density between the Cu electrode and each intermetallic compound. Accordingly, excellent reliability of connection between the Cu electrode and the solder alloy can be obtained.

According to a second aspect of the present invention, there is provided a semiconductor device wherein the solder alloy is formed of solder in which a composition ratio of the above Bi ranges from 32 wt % or more to 75 wt % or less.

According to the semiconductor device related to second aspect, since the composition of Bi is 75 wt % or less, connection reliability can be maintained without deteriorating the strength of solder itself. Since the content of Bi is 32 wt % or more, stopper portions each containing Bi necessary to inhibit the growth of each intermetallic compound can be formed sufficiently. Thus, excellent connection reliability can be obtained.

According to a third aspect of the present invention, there is provided a semiconductor device wherein the solder alloy contains Ag.

According to the semiconductor device related to the third aspect, since each stopper portion containing Ag in a manner similar to Bi can be formed, it is possible to inhibit the growth of each intermetallic compound more effectively. Ag forms an alloy with Sn. The formed alloy can be made adjacent to the Cu electrode and the intermetallic compound without allowing the Cu electrode and the intermetallic compound to be solid-soluble in each other. The stopper portion containing Ag inhibits the growth of each intermetallic compound together with Bi, thus making it possible to obtain excellent connection reliability. Since Ag forms the alloy with Sn, the amount of Sn in the composition of the solder alloy is reduced so that the growth of the intermetallic compound can be inhibited.

According to a fourth aspect of the present invention, there is provided a semiconductor device wherein the stopper portion comprises an element having a positive enthalpy of mixing at the time that it is mixed into Cu or the respective intermetallic compounds, or the element and a compound.

According to the semiconductor device related to the fourth aspect, since the stopper portion is not solid-soluble in Cu and the intermetallic compound, the stopper portion can adjoin the Cu electrode and the intermetallic compound. Thus, since the stopper portion can surround its corresponding intermetallic compound, the area at which Sn in the solder composition and the intermetallic compound contact with each other is reduced and hence the growth of each intermetallic compound is suppressed, thereby making it possible to obtain excellent connection reliability.

According to a fifth aspect of the present invention, there is provided a semiconductor device wherein the stopper portion comprises Bi or Bi and Ag3Sn.

According to the semiconductor device related to the fifth aspect, the stopper portion can be formed without causing Bi corresponding to a component essential for solder composition to be solid-soluble in Cu. Since Ag3Sn is not solid-soluble in Cu, it functions as the stopper portion in a manner similar to Bi and excellent connection reliability can be obtained.

According to the present invention, there can be provided a semiconductor device excellent in the reliability of connection between the semiconductor device and a mounting board.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a sectional view of a semiconductor device according to an embodiment of the present invention;

FIG. 2 is a sectional view of the semiconductor device according to the embodiment of the present invention, which is mounted onto a mounting board;

FIG. 3(A) is a sectional view of a semiconductor device of the present invention, FIG. 3(B) is an SEM photograph of the neighborhood of an interface between a CU electrode and a solder alloy, and FIG. 3(C) is a typical view showing the neighborhood of the interface between the Cu electrode and the solder alloy;

FIG. 4 is a sectional view of a semiconductor device according to an embodiment of the present invention;

FIG. 5 is a process view showing a method for forming external connecting terminals of a semiconductor device according to an embodiment of the present invention and is a process view illustrating a method for mounting the semiconductor device according to the embodiment of the present invention onto a mounting board;

FIG. 6 is a view indicative of temperature cycle conditions in a chamber at the evaluation of thermal shock reliability;

FIG. 7 is a graph indicating the dependence of thermal shock reliability on a composition ratio of Bi in each external connecting terminal;

FIG. 8 is a schematic view of a method for measuring the number of repetitive bending fracture cycles; and

FIG. 9(A) is a sectional view of a conventional semiconductor device, FIG. 9(B) is an SE photograph of the neighborhood of an interface between a Cu electrode and solder, and FIG. 9(C) is a typical view of the neighborhood of the interface between the Cu electrode and a solder alloy.

### DETAILED DESCRIPTION OF THE PREFERRED EMBODIMENTS

Preferred embodiments of the present invention will hereinafter be described with reference to the accompanying drawings.

### <Semiconductor Device>

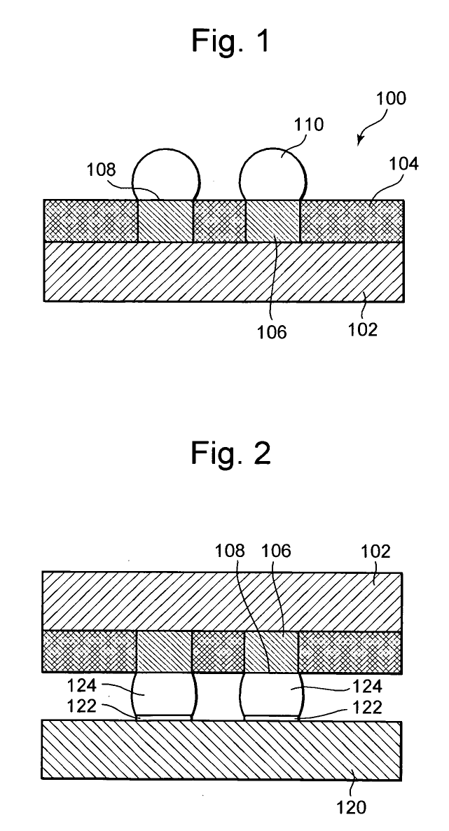

FIG. 1 is a sectional view of a semiconductor device 100 of the present invention.

The semiconductor device 100 shown in FIG. 1 includes an electric circuit formed on a substrate 102 by a known wafer process and is formed with a semiconductor element or chip (not shown). Wirings (not shown) respectively electrically connected to electrode pads (not shown) electrically connected to the electric circuit are formed. An insulating resin layer 104 is formed on the substrate 102 in such a manner that Cu electrodes 106 of parts of the wirings (not shown) are exposed. Further, external connecting terminals 110 are formed on the Cu electrodes 106 respectively.

FIG. 2 is a sectional view of the semiconductor device 100 of the present invention, which has been mounted on a printed circuit board or mounting board 120.

The external connecting terminals 110 of the semiconductor device 100 are mounted on the opposite side of the mounting board 120 via junctions 124 formed by being electrically connected to terminals 122 formed on the mounting board 120.

The external connecting terminals 110, the wirings 106, the insulating resin layer 104 and the substrate 102 will be described in detail below.

### [External Connecting Terminal]

Each of the external connecting terminals 110 according to the present invention features that it has a Cu electrode, intermetallic compounds containing Cu formed on the Cu electrode, stopper portions which cover the surfaces of the intermetallic compounds at intervals, and a solder alloy comprising Bi and an impurity containing Sn formed on the stopper portions and the intermetallic compounds.

The stopper portions, intermetallic compounds, solder alloy and Cu electrode that constitute the external connecting terminal 110 will be described in detail below.

### ‘Stopper Portion]

The semiconductor device of the present invention has the stopper portions. In the present invention, the “stopper portion” indicates a constituent or component part for inhibiting the growth of the intermetallic compound to the solder alloy side. The layout and composition of each stopper portion will be described in detail below.

### Layout of Stopper Portion

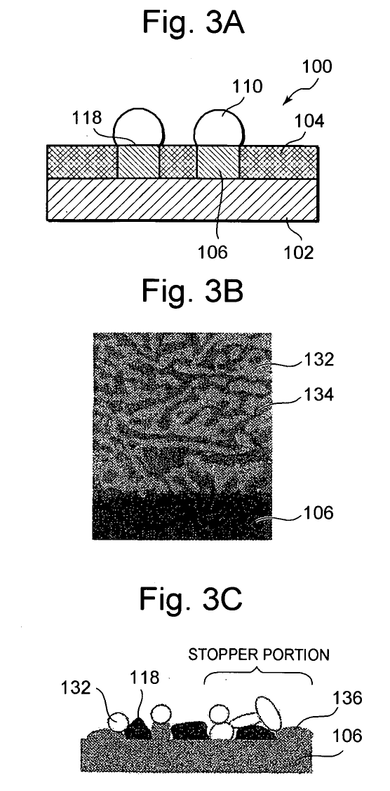

The stopper portion according to the present invention is formed in the neighborhood of an interface between the Cu electrode and its corresponding external connecting terminal and disposed or laid out so as to surround each intermetallic compound formed of both Cu of the Cu electrode and Sn in the composition of the solder alloy. It will be described in detail below using FIG. 3.

FIG. 3(A) is a sectional view of a semiconductor device of the present invention, FIG. 3(B) is an SEM photograph of the neighborhood of an interface between a Cu electrode and its corresponding external connecting terminal, and FIG. 3(C) is a typical view of the neighborhood of the interface between the Cu electrode and the external connecting terminal. As shown in FIG. 3(C), intermetallic compounds 118 are formed on the Cu electrode 106. Stopper portions each composed of Bi 132 and Ag3Cu 136 surround or cover the intermetallic compounds 118 at intervals. Here, the “covering” represents that part of the intermetallic compound is covered with the corresponding stopper portion. The part thereof will be described in detail. “The intervals” of “at intervals” represent the intervals of the stopper portions capable of inhibiting the growth of the intermetallic compounds and are intervals determined suitably according to the shapes or widths of the intermetallic compounds. Described specifically, when the stopper portions are formed at intervals of 2 to 3 μm or less, the growth of each intermetallic compound can be inhibited.

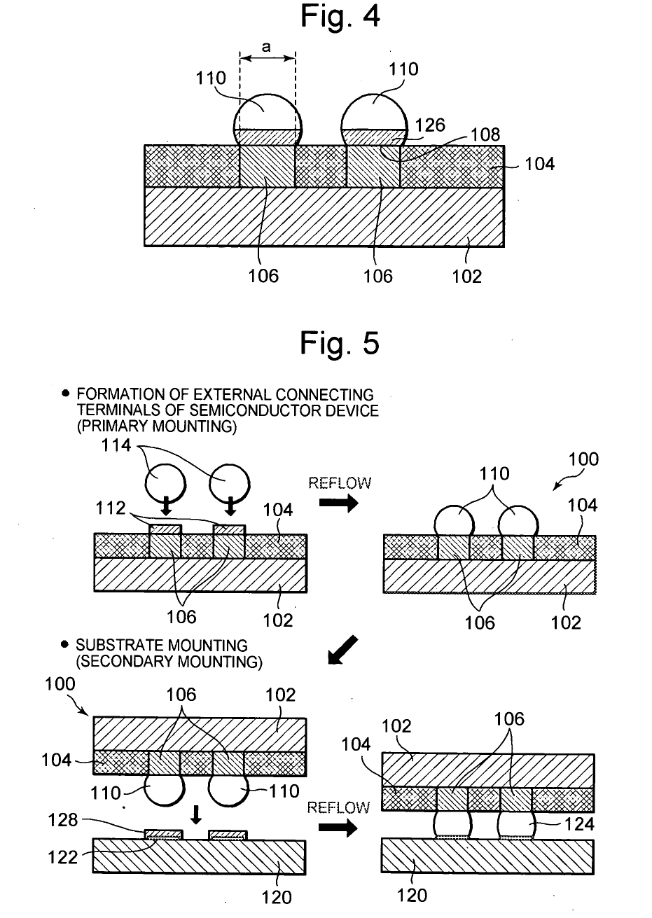

The “part” indicates that the stopper portion is provided in a range from 25% or more to 85% or less of a width a of an interface between a Cu electrode and its corresponding external connecting terminal as shown in FIG. 4. As its range, may be mentioned, more preferably, a range from 35% or more to 75% or less thereof. When 25% or less is reached, the stopper portion for inhibiting the growth of each intermetallic compound falls short. When 85% or more is reached, the phase of the stopper portion is precipitated even inside the external connecting terminal and the strength of a solder alloy itself is hence deteriorated.

### Composition of Stopper Portion

The stopper portion according to the present invention is preferably composed of an element having a positive enthalpy of mixing at the time that it is mixed into Cu or the respective intermetallic compounds or composed of the element and a compound. The “enthalpy of mixing” means internal energy of a substance placed in a solid or liquid state. Namely, it means that when the element having the positive enthalpy of mixing or the compound is mixed, the internal energy of a mixture becomes high, and the two elements kept in equilibrium or compounds have a strong tendency to separate. Accordingly, an element having a positive enthalpy of mixing, which is not solid-soluble in Cu, or the element and a compound are precipitated and adjoin Cu and intermetallic compounds, thereby making it possible to form stopper portions.

Thus, any element and compound may be adopted if ones hard to be solid-soluble in Cu and the intermetallic compounds are taken. As elements each having a positive enthalpy of mixing with Cu, may be mentioned, for example, V, Cr, Mn, Fe, Co, Ni, Ru, Ag, W, Na, TI, Pb and Bi according to (COHESION IN ALLOYS-FUNDAMENTALS OF A SEMI-EMPIRICAL MODEL (Physica 100B(1980) 1-28)). Even of these, Bi is preferred in terms of formability of each stopper portion. As the compounds, may be mentioned, for example, Au—Sn (AuSn4, AuSn2, AuSn), Ni—Sn (Ni3Sn, Ni3Sn2, Ni3Sn4) and Ag3Sn from the viewpoint that Sn is an element essential to the composition of solder. Even of these, Ag3Sn (Sn: 26.8 wt % and remainder Ag) is preferred from the viewpoint of suppressing an increase in internal stress due to the production of many kinds of intermetallic compounds due to a variation with time. Further, as a particularly preferred form, there may be mentioned to form a stopper portion composed of Bi and a stopper portion composed of Ag3Sn simultaneously because a junction strength is enhanced when Ag and Sn coexist.

At the aforementioned stopper portions, (Bi):(Ag3Sn)=100:0 to 56:44 is particularly preferred as the ratio in area between the stopper portion composed of Bi and the stopper portion composed of Ag3Sn. When the ratio falls within these ranges, the element Sn in the neighborhood of the interface between the Cu electrode and the solder alloy is substituted with Ag3Sn, so that the amount of supply of Sn can be reduced. It is therefore possible to effectively inhibit the growth of the intermetallic compound and obtain high connection reliability.

### [Intermetallic Compound]

Each of the intermetallic compounds according to the present invention contains Cu for the Cu electrode and is a compound of Cu and an element in the composition of a solder alloy. As such intermetallic compounds, may be mentioned, for example, Cu6Sn5, Cu3Sn, CuZn, Cu5Zn8, etc. The element essential to the composition of solder is Sn, and Cu6Sn5 and Cu3Sn are preferably cited in terms of ease of handling. When these intermetallic compounds are grown due to a variation with time, local stress occurs. This is inferred as follows: The density of Cu6Sn5 is 8.3g/cm³, and the density of Cu3Sn is 11.3 g/cm³. On the other hand, the density of Cu is 8.9 g/cm³. When Cu6Sn5 is formed, the volume thereof expands because Cu6Sn5 is lower in density than Cu. When Cu3Sn is formed, the volume thereof shrinks because Cu3Sn is higher in density than Cu. Accordingly, the volumetric expansion and shrinkage lead to the occurrence of local stress, and the Cu electrode and the solder alloy become easy to peel off, thus causing deterioration of connection reliability.

Since the growth of the intermetallic compound according to the present invention is inhibited by the stopper portion, the thickness thereof is thin at or below 3 μm and a variation in the thickness thereof is also small. As the variation in the thickness of the intermetallic compound, −45% or more to +63% or less is preferred with respect to the average value of the thickness of the intermetallic compound. Particularly preferred is −45% or more to +27% or less. When the variation falls therewithin, there are no grown spots in the intermetallic compound and no local stress occurs. It is therefore possible to obtain high connection reliability.

### [Solder Alloy]

Each of the external connecting terminals according to the present invention has a solder alloy composed of Bi and an impurity containing Sn.

“The impurity containing Sn” represents an impurity containing Sn as a principal component. Sn may be 100%.

As a preferred embodiment or form, the composition ratio of Bi in the solder alloy includes 32 wt % or more to 75 wt % or less. As a further preferred embodiment or form, the composition ratio includes 41 wt % or more to 74 wt % or less. When Bi falls within the range, connection reliability is remarkably enhanced than conventional. This shows the tendency that the phase composed of Bi in the solder alloy is gravitated to the peripheries of a Cu electrode and an intermetallic compound due to the fact that Bi is contained a predetermined amount or more. Thus, since the stopper portions are formed in the neighborhood of the Cu electrode and the intermetallic compound, the growth of the intermetallic compound can be inhibited. When the content of Bi is 75 wt % or more, the solder alloy itself is deteriorated in ductility and inferior in processability, strength and durability. Since the growth of the intermetallic compound is inhibited when it is 32 wt % or less, the stopper portion necessary to inhibit the growth of each intermetallic compound is hard to be formed.

As a further preferred embodiment or form, the solder alloy composed of Bi and the impurity containing Sn includes composition containing Ag. With Ag contained therein, an intermetallic compound composed of Ag and Sn in the composition of the solder alloy is formed as a stopper portion, and the content of Sn in the composition of the solder alloy is reduced, thereby making it possible to inhibit the growth of the intermetallic compound. As the composition of the stopper portion at the time that Ag is contained in the solder alloy, there is cited As3Sn as a compound in addition to the aforementioned Bi. The composition ratio of Ag in the solder alloy is not limited in particular if a compound (compound whose enthalpy of mixing with Cu or respective intermetallic compounds is positive) which is not solid-soluble in a Cu electrode to be described later and the above intermetallic compound is formed. Preferably, the composition ratio of Ag includes 0.2 wt % or more to 3.3 wt % with respect to the solder alloy. When it is 0.2 wt % or less, the stopper portion containing Ag enough to inhibit the growth of each intermetallic compound is not formed. When the composition ratio is 3.3 wt % or more, a compound containing Ag is precipitated or deposited everywhere in the solder alloy and the strength of the solder alloy itself against cracks made from the precipitated spots is lowered. A liquidus line of An54bi4Ag composition added with Ag of 4 wt % exceeds 300° C. and hence a semiconductor device per se cannot be manufactured.

As a particularly preferred form even of the above solder alloy, the composition ratio of Bi in the solder alloy includes 32 wt % or more to 75 wt % or less, the composition ratio of Ag includes 0.2 wt % or more to 3.3 wt % or less, and the remainder includes Sn.

### [Cu Electrode]

As the Cu electrode 106 used in the semiconductor device of the present invention, the known Cu can be used.

### [Insulating Seal Layer]

The semiconductor device illustrated in the present invention has an insulating seal layer 104. This is provided with the aim of suppressing corrosion of wirings each rewired from an electrode pad of a semiconductor chip, or shielding light on a device circuit surface, for example.

The material for the insulating seal layer 104 is not limited in particular if it has an insulting property and adhesion (lightproof property as needed). As its material, may be mentioned, for example, polyimide, a thermosetting epoxy resin, bismaleiimide or the like. Even of these, the thermosetting epoxy resin is preferred as the material in terms of the ability to form the thickness of the insulating seal layer and its cost or the like.

60 to 100 μm is preferred as the thickness of the insulating seal layer 104 in terms of moisture resistant reliability and lightproofness or the like.

### [Substrate]

The semiconductor device 100 of the present invention has a substrate 102.

The material of the substrate includes silicon or the like.

As the thickness of the substrate, 400 μm or less is preferred to handle miniaturization or the like of the semiconductor device.

With the use of the above semiconductor device, the ratio of life of connection of the substrate to a printed circuit board or mounting board 120 at the time that thermal or heat shock is applied thereto after the semiconductor device has been mounted onto the mounting board 120, can be dramatically enhanced as compared with the conventional semiconductor device.

### <Manufacturing Method of Semiconductor Device and Mounting of Semiconductor Device>

One example of a method for manufacturing the semiconductor device of the present invention will be described below in accordance with FIG. 5.

In the semiconductor device 100 of the present invention, the known wafer process is performed on a substrate 102 and semiconductor chips (not shown) arranged in matrix form are formed in the surface of the substrate 102. The semiconductor chip described herein means an electric circuit on the substrate, which is formed in association with one semiconductor device.

After each electrode pad (not shown) electrically connected to the electric circuit has been formed, an insulating layer (not shown) composed of a resin material such as polyimide is applied onto the surface of the substrate 102 by spin coating or the like. Of the applied polyimide, polyimide at each unnecessary spot is removed by the know photolithography technology or the like. By these process steps, the insulating layer (not shown) composed of polyimide or the like is formed on the surface of the substrate 102 excepting an area corresponding to each electrode pad (not shown) and an area extending along the boundary line between the semiconductor chips (not shown).

A barrier metal (not shown) composed of titanium tungsten (TiW) or the like is formed on the surface thereof by, for example, an ion sputter method. Thereafter, the barrier metal is plated with copper (Cu) to perform wiring so as to extend from each electrode pad (not shown) to the upper surface of the insulating seal layer 104, thereby forming each Cu electrode 106.

Next, flux 112 is applied to electrically connect solder balls 114 and the Cu electrodes respectively. Thereafter, the solder balls 114 are placed on the flux 112 and reflow processing is done to form external connecting terminals 110.

As the flux suitably usable in the semiconductor device of the present invention here, may be mentioned, for example, resinous flux and organic acid flux. Even of these, the flux 112 suitably usable in the present invention may include halogen-free flux in any case. Further, flux that meets the following is preferred in view of a reflow processing temperature.

Preferably, the boiling point of a flux solvent is set to 140° C. or higher to 300° C. or below and the temperature at which activity begins to appear, is set to 80° C. or higher to 160° C. or less. A more preferred embodiment or form, there is cited that the boiling point of a solvent is set to 180° C. or more to 285° C. or less, and the temperature at which activity begins to appear is 100° C. or higher to 140° C. or lower.

Reflow processing is performed as follows: Preheating for making a substrate temperature uniform at, for example, 150° C. is carried out and thereafter the temperature is continuously raised to a peak temperature to perform solder joining. The reflow process may preferably be performed in the atmosphere assuming that as a condition (hereinafter suitably called “peak condition”) for rising to the peak temperature, a temperature rise/drop rate ranges from 2° C./minute to 3° C./minute, the peak temperature ranges from 180° C. to 260° C., and the holding time at above (peak temperature—20° C.) ranges from 30 seconds to 60 seconds. If the reflow process is performed assuming that the peak temperature ranges from 240° C. to 260° C. among them, it is then preferable in terms of a stopper portion being formed sufficiently.

As an alternative to the flux 112, solder paste 112 having the same composition as the alloy composition of each external connecting terminal 110 referred to above may be used. As the composition of the solder paste, Sn3Ag0.5Cu that has heretofore been used may be used.

The semiconductor device 100 of the present invention, which has been manufactured in this way, is mounted onto its corresponding mounting board 120.

An electric circuit is formed on the mounting board 120 by the known method, and solder paste 128 is applied onto terminals 122 electrically connected to the electric circuit. As the composition of the solder paste 128, may be mentioned, for example, Sn(_{100-x-y})AgₓCu_{y} (where _{x and y} indicative of a composition ratio respectively range from 0.05 wt % or more to 5 wt % less and from 0.05 wt % more to 2 wt % or less). Thereafter, the semiconductor device 100 of the present invention manufactured in the above-described manner is disposed on the solder paste 128 in such a manner that the external connecting terminals 110 are placed on the solder paste 128, after which the reflow process is performed to electrically connect the external connecting terminals 110 and the terminals 122, whereby the mounting of the semiconductor device 100 on the mounting board 120 is completed.

### PREFERRED EMBODIMENTS

Although the present invention is described in more detail below by embodiments, the present invention is not limited to or by the embodiments.

### First Embodiment

In a first embodiment, a semiconductor device was manufactured in which the alloy composition of each external connecting terminal of the semiconductor device was SnBi (Sn: 59 wt % and Bi: 41 wt %) and each stopper portion was provided around a Cu electrode and each intermetallic compound.

### (Fabrication of Semiconductor Device)

The present embodiment will be described along FIG. 5. The known wafer process is performed on the corresponding substrate 102 to form a semiconductor chip in which wirings are arranged in matrix form. Thereafter, an insulating resin composed of polyimide is applied onto the semiconductor chip by spin coating and then dried, thereby forming an insulating layer (not shown) of 5 μm. Then, an area other than electrode pads is covered with a mask to expose the electrode pads. After exposure, development processing was conducted to expose the electrode pads. Next, a seed layer composed of titanium or the like is formed by an ion sputter method. Then, copper wirings and electrode pads of copper are formed by photolithography technology to re-distribute or relocate the electrode pads of the semiconductor chip in area form. Next, copper is precipitated directly on the electrode pads of copper by electrolytic plating. After that, the seed layer is etched to complete each copper redistribution wiring. Next, the whole part is sealed with a resin and thereafter the resin is ground to form Cu electrodes 106 each having a diameter of 250 μm, whose parts have been exposed from an insulating seal layer 104.

In order to remove an oxide film lying on the surface of each Cu electrode 106 and join solder and copper, flux 112 (Deltalux 523H made by Senju Metal Industry Co., Ltd.) was printed on the formed Cu electrodes 106 such that the coated thickness of the flux 112 became 60 μm. Thereafter, solder balls 114 having a diameter of Φ0.3 mm and a composition of SnBi (Sn: 59 wt % and Bi: 41 wt %) were mounted.

After the solder balls 114 have been mounted, a reflow process (XNIII-725PC(b): made by Furukawa Electric Co., Ltd.) is performed to electrically connect the CU electrodes 106 and the solder balls 114, thereby forming external connecting terminals 110, whereby a semiconductor device 100 is fabricated. The height (as viewed from the surface of each Cu electrode) of each external connecting terminal 110 was 250 μm.

Incidentally, a peak condition for the reflow process was that the temperature rise/drop rate was 2.5° C./minute, the peak temperature was 200° C. and the processing time at 180° C. or higher was one minute.

### (Evaluation)

### Thickness of Intermetallic Compound and Proportion of Stopper Portion

A fracture surface of the semiconductor device obtained in the above-described manner was obtained by selecting an area in the neighborhood of an interface between a Cu electrode and a solder alloy and photographing the interface by the scanning electron microscope (type: S-3600N made by Hitachi High-Technologies Corp.) under 1500× magnification. Thereafter, the thickness of Cu6Sn5 and/or Cu3Sn reflected or displayed on the photographed image was measured. The result of measurement is shown in Table 1. Incidentally, 0 μm indicative of the thickness of the intermetallic compound in Table represents that the Cu electrode and the stopper portion are brought into contact with each other at the observation of the photographed SEM photograph. “The thickness of intermetallic compound” represents the thickness of each intermetallic compound that contacts the Cu electrode. “The thickness of intermetallic compound except for stopper portion” represents the thickness of each intermetallic compound except for part at which the Cu electrode and the stopper portion contact each other, or the stopper portion that borders on the intermetallic compound.

A variation was evaluated based on the proportion of displacement of the thickness of the intermetallic compound excepting for the stopper portion with respect to the average thereof. Incidentally, the processing of the section was conducted by mechanical polishing.

The proportion of the stopper portion was obtained by observing the interface between the Cu electrode and the solder alloy from the SEM photograph of the cut cross-section of the semiconductor device and determining the ratio or proportion of a coated width of each stopper portion. Incidentally, Bi, Sn, Cu6Sn5 and Cu3Sn were measured by the energy dispersive X-ray spectrometer(type: EX-250 made by HORIBA, Ltd.). The result of measurement is shown in Table 1.

### Second Through Fourth Embodiments and First Through Third Comparative Examples

A semiconductor device is fabricated in a manner similar to the first embodiment except that the composition of each external connecting terminal has been changed as shown in Table 1 in the first embodiment, and similar evaluation was conducted. The result thereof is shown in Table 1.

TABLE 1

| | Composition | | | | | | | | | | | | |
|---|---|---|---|---|---|---|---|---|---|---|---|---|---|
| | of external | | | | | | | | | | | | |
| | connecting terminal | | | | Height of | | | Thickness of intermetallic | | | | Proportion of | |
| | of semiconductor | | | | intermetallic | | | compound | | | | stopper | |
| | device (wt %) | | | | compound (μm) | | | except for stopper portion (μm) | | | | portion (%) | |
| | Bi | Ag | Cu | Sn | Ave. | Max. | Min. | Ave. | Max. | Min. | Variation | Bi | Ag3Sn |
| First | 41.0 | 0.0 | 0.0 | 59.0 | 1.7 | 2.5 | 0.0 | 2.0 | 2.5 | 1.1 | +25%/−45% | 35 | 0 |
| embodiment | | | | | | | | | | | | | |
| Second | 58.0 | 0.0 | 0.0 | 42.0 | 1.1 | 1.8 | 0.0 | 1.1 | 1.8 | 0.9 | +63%/−19% | 43 | 0 |
| embodiment | | | | | | | | | | | | | |
| Third | 74.0 | 0.0 | 0.0 | 26.0 | 0.8 | 1.4 | 0.0 | 1.1 | 1.4 | 0.7 | +27%/−36% | 85 | 0 |
| embodiment | | | | | | | | | | | | | |
| Fourth | 58.0 | 1.0 | 0.0 | 41.0 | 0.7 | 1.2 | 0.1 | 1.0 | 1.2 | 0.7 | +20%/−30% | 50 | 28 |
| embodiment | | | | | | | | | | | | | |
| First | 0.0 | 3.0 | 0.5 | 96.5 | 2.2 | 4.4 | 0.4 | 2.2 | 4.4 | 0.4 | +100%/−82% | — | — |
| comparative | | | | | | | | | | | | | |
| example | | | | | | | | | | | | | |
| Second | 9.0 | 0.0 | 0.0 | 91.0 | 1.9 | 3.2 | 0.5 | 2.9 | 3.2 | 2.7 | +10%/−7% | 17 | 9 |
| comparative | | | | | | | | | | | | | |
| example | | | | | | | | | | | | | |
| Third | 84.0 | 0.0 | 0.0 | 16.0 | 0.7 | 1.2 | 0.0 | 1.0 | 1.2 | 0.6 | +20%/−40% | 92 | 0 |
| comparative | | | | | | | | | | | | | |
| example | | | | | | | | | | | | | |

It is understood from Table 1 that in the embodiment of the present invention, any of the thicknesses of the intermetallic compounds excepting the stopper portions is 3 μm or less and a variation in the intermetallic compound is also small.

### Fifth Embodiment

A semiconductor device obtained by performing processing as in the first embodiment is mounted on its corresponding mounting board. Its mounting method will be described below.

### (Mounting of Semiconductor Device on Mounting Board)

Solder paste having a composition of Sn(_{100-x-y})AgₓCu_{y} (where x=3 wt % and y=0.5 wt %) is printed on each electrode pad (material: copper) formed in a mounting board (QSX-33398: made by Eastern Co., Ltd.) composed of a compound of glass and an epoxy resin via a metal mask interposed therebetween. Thereafter, each connecting terminal of the semiconductor device is mounted on the solder paste and a reflow process (XNIII-725PC(b): made by Furukawa Electric Co., Ltd.) is performed to mount the semiconductor device on the mounting board.

Incidentally, the condition for the reflow process was that the temperature rise/drop rate was 2.5° C./minute, the peak temperature was 240° C. and the holding time at 220° C. was one minute. The composition of the junction between the semiconductor device and the mounting board was Sn (_{100-x-y-z})BiₓAg_{y}Cu_{z} (where x=29.1 wt %, y=1.5 wt % and z=0.3 wt %)

### (Evaluation)

### Thickness of Intermetallic Compound and Proportion of Stopper Portion

In a manner similar to the first embodiment, a photograph of a fracture section of a post-mounting sample is taken, and the thickness of each intermetallic compound and the proportion of each stopper portion were evaluated. The result thereof is shown in Table 2.

### Sixth and Seventh Embodiments and Fourth Through Sixth Comparative Examples

A semiconductor device is mounted onto a mounting board in a manner similar to the fifth embodiment except that the composition of each external connecting terminal has been changed as shown in Table 2 in the fifth embodiment, and similar evaluation was conducted. The result thereof is shown in Table 2.

TABLE 2

| | Composition of | | | | Composition of | | | | | | | | | | | | |
|---|---|---|---|---|---|---|---|---|---|---|---|---|---|---|---|---|---|
| | external connecting | | | | junction between | | | | | | | | | | | | |
| | terminal of | | | | semiconductor | | | | | | | | | | | | |
| | semiconductor | | | | device and | | | | Height of | | | Thickness of intermetallic | | | | Proportion | |
| | device | | | | mounting | | | | intermetallic | | | compound | | | | of stopper | |
| | (wt %) | | | | board (wt %) | | | | compound (μm) | | | except for stopper portion (μm) | | | | portion (%) | |
| | Bi | Ag | Cu | Sn | Bi | Ag | Cu | Sn | Ave. | Max. | Min. | Ave. | Max. | Min | Variation | Bi | Ag3Sn |
| Fifth | 41.0 | 0.0 | 0.0 | 59.0 | 29.1 | 1.5 | 0.3 | 69.1 | 3.2 | 4.2 | 0.0 | 3.3 | 4.2 | 2.3 | +27%/−30% | 32 | 10 |
| embodiment | | | | | | | | | | | | | | | | | |
| Sixth | 58.0 | 0.0 | 0.0 | 42.0 | 48.1 | 0.5 | 0.1 | 51.3 | 2.3 | 4.2 | 0.0 | 3.6 | 4.2 | 3.2 | +17%/−11% | 52 | 20 |
| embodiment | | | | | | | | | | | | | | | | | |
| Seventh | 74.0 | 0.0 | 0.0 | 26.0 | 61.9 | 0.5 | 0.1 | 37.5 | 2.4 | 4.7 | 0.8 | 3.6 | 4.7 | 2.4 | +31%/−33% | 72 | 10 |
| embodiment | | | | | | | | | | | | | | | | | |
| Fourth | 0.0 | 3.0 | 0.5 | 96.5 | 0.0 | 3.0 | 0.5 | 96.5 | 5.5 | 8.6 | 0.9 | 5.5 | 8.6 | 0.9 | +56%/−84% | — | 0 |
| comparative | | | | | | | | | | | | | | | | | |
| example | | | | | | | | | | | | | | | | | |
| Fifth | 9.0 | 0.0 | 0.0 | 91.0 | 3.7 | 2.8 | 0.5 | 93.0 | 4.2 | 6.5 | 0.7 | 4.8 | 6.5 | 4.1 | +35%/−15% | 1 | 26 |
| comparative | | | | | | | | | | | | | | | | | |
| example | | | | | | | | | | | | | | | | | |
| Sixth | 84.0 | 0.0 | 0.0 | 16.0 | 70.6 | 0.5 | 0.1 | 28.8 | 2.3 | 5.1 | 0.9 | 3.7 | 5.1 | 2.3 | +35%/−38% | 79 | 15 |
| comparative | | | | | | | | | | | | | | | | | |
| example | | | | | | | | | | | | | | | | | |

### Eighth Embodiment

After the semiconductor device has been mounted on the mounting board in the fifth embodiment, a temperature cycle process shown below is conducted, and the thickness of each intermetallic compound and the proportion of each stopper portion were evaluated in a manner similar to the fifth embodiment. Thermal shock reliability, a repetitive bending fracture cycle ratio and a repetitive drop fracture cycle ratio such as shown below were evaluated. The result thereof is shown in Table 3.

### Thermal Shock Reliability

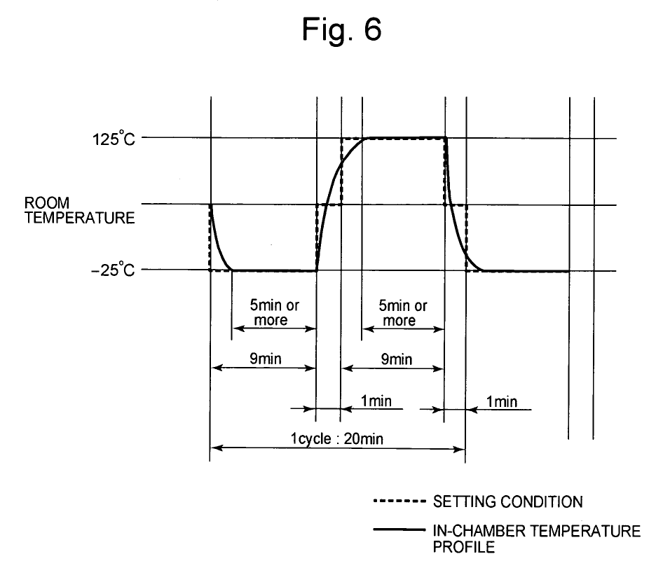

One in which the semiconductor device has been mounted onto the mounting board is inserted into a thermal shock test chamber (TSA-101S-W: made by ESPEC Co., Ltd.) and left in the atmosphere under a temperature cycle condition shown in FIG. 6. The electric resistance value of a junction between the semiconductor device and the mounting board is measured in real time simultaneously with the start of a temperature cycle. Next, electric resistance values on the high-temperature and low-temperature sides at the first cycle of the temperature cycle are set as initial resistance values and compared therewith, after which the number of cycles at the time of an increase of 50% was plotted on Weibull probability paper. The number of cycles that cause a 0.1% failure is read from a graph (vertical axis: cumulative defect rate, and horizontal axis: number of cycles) in which the number of defective cycles has been plotted. Thereafter, thermal shock reliability was examined or investigated assuming that the value in a seventh comparative example in which the composition of the junction between the semiconductor device and the mounting board be SnAgCu (Sn: 96.5 wt %, Ag: 3.0 wt % and Cu: 0.5 wt %) is 1.0. The result of investigation is shown in Table 3.

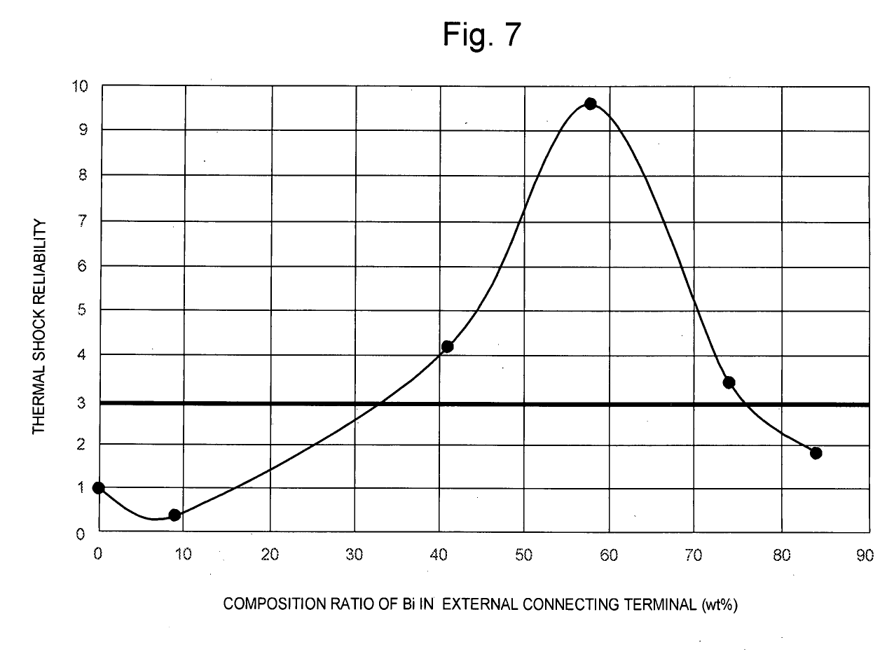

The relationship between thermal shock reliability and a Bi composition ratio at each external connecting terminal of the semiconductor device is shown in FIG. 7.

### Repetitive Bending Fracture Cycle-Number Ratio

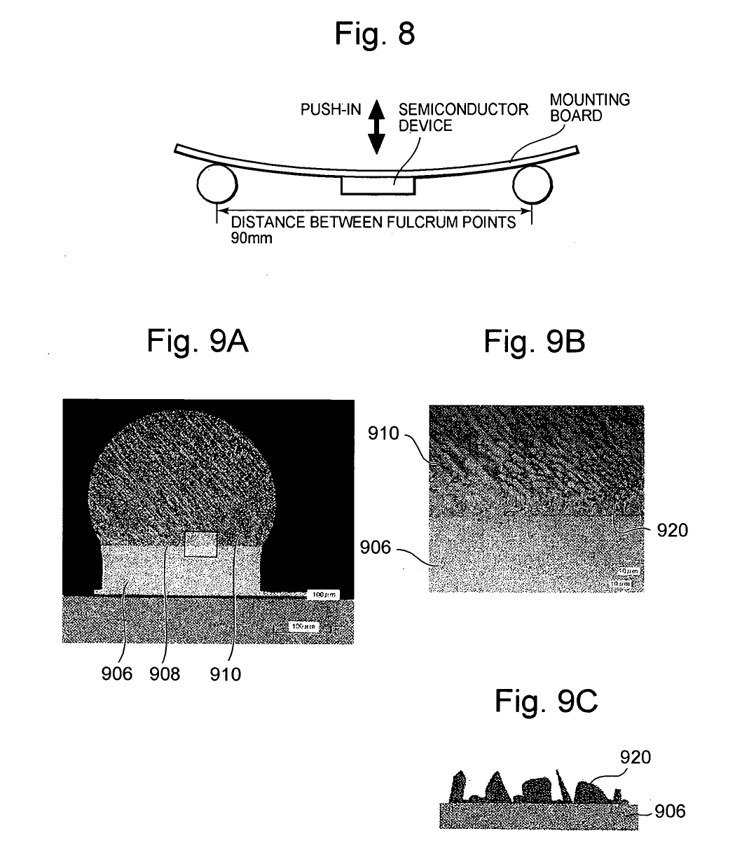

The mounting board mounted with the semiconductor device mounted thereon is placed on a fulcrum point by a method shown in FIG. 8 in accordance with ET-7409/105 of JEITA standard, and the following push-in amount is repeatedly applied as a load from the back side of the mounting board, whereby the number of repetitive bending fracture cycles at the fracture was measured. Test conditions will be described as follows:
Distance between fulcrum points: 90 mm
Push-in amount: 4 mm
Push-in rate: 0.5 mm/s
Specs of semiconductor device: □6 mm/0.5 mm pitch
Mounting board: 40 mm×110 mm×1 mm

A repetitive bending fracture cycle-number ratio was examined or investigated assuming that the number of the repetitive bending fracture cycles in the seventh comparative example in which the composition of the junction between the semiconductor device and the mounting board be SnAgCu (Su: 96.5 wt %, Ag: 3.0 wt % and Cu: 0.5 wt %) is 1. The result of investigation is shown in Table 3.

### Repetitive Drop Fracture Cycle-Number Ratio

A mounting board (52.5×105.0 mm) with a semiconductor device mounted thereto is fixed onto an aluminum jig 150 g in accordance with ET-7409/105 of JEITA standard and dropped onto a falling surface made of concrete repeatedly freely from a height of 1.5 m. The number of repetitive drop fracture cycles at the time that a change in the resistance value of the mounting board has reached 20% or more, was measured.

A repetitive drop fracture cycle-number ratio was examined or investigated assuming that the number of the repetitive drop fracture cycles in the seventh comparative example in which the composition of the junction between the semiconductor device and the mounting board be SnAgCu (Su: 96.5 wt %, Ag: 3.0 wt % and Cu: 0.5 wt %) is 1. The result of investigation is shown in Table 3.

### Ninth and Tenth Embodiments and Seventh Through Ninth Comparative Examples

A semiconductor device is mounted onto a mounting board in a manner similar to the eighth embodiment except that the composition of each external connecting terminal has been changed as shown in Table 3 in the eighth embodiment, and similar evaluation was conducted. The result thereof is shown in Table 3.

TABLE 3

| | Composition of | | | | Composition | | | | | | | | | | |
|---|---|---|---|---|---|---|---|---|---|---|---|---|---|---|---|
| | external connecting | | | | of junction | | | | | | | | | | |
| | terminal of | | | | between | | | | | | | | | | |
| | semiconductor | | | | semiconductor | | | | Height of | | | Thickness of | | | |
| | device | | | | device and mounting | | | | intermetallic | | | intermetallic compound | | | |
| | (wt %) | | | | board (wt %) | | | | compound (μm) | | | except for stopper portion (μm) | | | |
| | Bi | Ag | Cu | Sn | Bi | Ag | Cu | Sn | Ave. | Max. | Min. | Ave. | Max. | Min. | Variation |
| Eighth embodiment | 41.0 | 0.0 | 0.0 | 59.0 | 29.1 | 1.5 | 0.3 | 69.1 | 3.2 | 3.7 | 1.4 | 3.2 | 3.7 | 1.6 | +16%/−19% |
| Ninth embodiment | 58.0 | 0.0 | 0.0 | 42.0 | 48.1 | 0.5 | 0.1 | 51.3 | 3.0 | 4.2 | 0.9 | 3.0 | 4.1 | 2.1 | +37%/−30% |
| Tenth embodiment | 74.0 | 0.0 | 0.0 | 26.0 | 61.9 | 0.5 | 0.1 | 37.5 | 3.7 | 6.5 | 1.8 | 4.5 | 6.4 | 2.7 | +42%/−40% |
| Seventh comparative | 0.0 | 3.0 | 0.5 | 96.5 | .0.0 | 3.0 | 0.5 | 96.5 | 6.8 | 10.5 | 0.9 | 6.8 | 10.5 | 0.9 | +54%/−87% |
| example | | | | | | | | | | | | | | | |
| Eighth comparative | 9.0 | 0.0 | 0.0 | 91.0 | 3.7 | 2.8 | 0.5 | 93.0 | 4.2 | 6.5 | 1.4 | 4.2 | 6.5 | 3.6 | +55%/−14% |
| example | | | | | | | | | | | | | | | |
| Ninth comparative | 84.0 | 0.0 | 0.0 | 16.0 | 70.6 | 0.5 | 0.1 | 28.8 | 3.7 | 6.9 | 1.8 | 5.3 | 6.4 | 4.5 | +21%/−15% |
| example | | | | | | | | | | | | | | | |

| | Proportion of | | | | |
|---|---|---|---|---|---|
| | stopper | | | | |
| | portion (%) | | | Repetitive bending | Repetitive drop |
| | Bi | Ag3Sn | Thermal shock realiability | fracture cycle ratio | fracture cycle ratio |
| Eighth embodiment | 8 | 17 | 4.2 | 1.0 | 1.0 |
| Ninth embodiment | 18 | 14 | 9.6 | 1.0 | 1.0 |
| Tenth embodiment | 74 | 7 | 3.4 | 0.9 | 0.8 |
| Seventh comparative | — | 0 | 1.0 | 1.0 | 1.0 |
| example | | | | | |
| Eighth comparative | 2 | 3 | 0.4 | 1.0 | 1.0 |
| example | | | | | |
| Ninth comparative | 85 | 9 | 1.8 | 0.4 | 0.3 |
| example | | | | | |

It is understood from Table 3 that even when the embodiment of the present invention is mounted onto the mounting board, a variation in the height of each intermetallic compound excepting each stopper portion is relatively small and each stopper portion for inhibiting the growth of the intermetallic compound is formed sufficiently.

In the embodiment of the present invention as understood from Table 3, even when thermal shock is applied, a repetitive bending fracture cycle ratio and a repetitive drop fracture cycle ratio are equal as compared with the conventional junction, and thermal shock reliability was remarkably enhanced.

### Eleventh and Twelfth Embodiments

A semiconductor device is fabricated in a manner similar to the second embodiment except that a peak temperature at reflow at the time that solder balls are connected to their corresponding Cu electrodes has been changed in the second embodiment, and similar evaluation was conducted. The result thereof is shown in Table 4.

TABLE 4

| | Composition of | | | | | | | | | | | | | | |
|---|---|---|---|---|---|---|---|---|---|---|---|---|---|---|---|
| | external connecting | | | | | | | | | | | | | | |
| | terminal of | | | | Peak temperature | | | | | | | | | Proportion | |
| | semiconductor | | | | at reflow (° C.) | | Height of | | | Thickness of intermetallic | | | | of | |
| | device | | | | At | At | intermetallic | | | compound except for stopper | | | | stopper | |
| | (wt %) | | | | terminal | substrate | compound (μm) | | | portion (μm) | | | | portion (%) | |
| | Bi | Ag | Cu | Sn | formation | mounting | Ave. | Max. | Min. | Ave. | Max. | Min. | Variation | Bi | Ag3Sn |
| Second | 58.0 | 0.0 | 0.0 | 42.0 | 200 | — | 1.1 | 1.8 | 0.0 | 1.1 | 1.6 | 0.9 | +45%/−18% | 43 | — |
| embodiment | | | | | | | | | | | | | | | |
| Eleventh | 58.0 | 0.0 | 0.0 | 42.0 | 240 | — | 1.5 | 2.3 | 0.0 | 1.8 | 2.3 | 1.4 | +28%/−22% | 64 | — |
| embodiment | | | | | | | | | | | | | | | |
| Twelfth | 58.0 | 0.0 | 0.0 | 42.0 | 260 | — | 1.6 | 2.3 | 1.1 | 2.1 | 2.3 | 1.4 | +10%/−33% | 60 | — |
| embodiment | | | | | | | | | | | | | | | |

As understood from Table 4, when the peak temperature at reflow is set to 240° C. and 260° C., the thickness of each intermetallic compound excepting the stopper portion and the proportion of the stopper portion were further increased.

### Thirteenth and Fourteenth Embodiments

A semiconductor device is mounted onto a mounting board in a manner similar to the eleventh embodiment except that a peak temperature at reflow at the time that the semiconductor device is mounted on the mounting board has been changed as shown in Table 5 in the eleventh embodiment, and similar evaluation was conducted. The result thereof is shown in Table 5.

TABLE 5

| | Composition | | | | | | | | | | | | | | | | | | |
|---|---|---|---|---|---|---|---|---|---|---|---|---|---|---|---|---|---|---|---|
| | of external | | | | Composition | | | | | | | | | | | | | | |
| | connecting | | | | of junction | | | | Peak temperature | | | | | | | | | | |
| | terminal of | | | | between | | | | at reflow (° C.) | | | | | | | | | | |
| | semiconductor | | | | semiconductor | | | | At | | Height of | | | Thickness of | | | | Proportion of | |
| | device | | | | device and mounting | | | | terminal | At | intermetallic | | | intermetallic compound | | | | stopper | |
| | (wt %) | | | | board (wt %) | | | | forma- | substrate | compound (μm) | | | except for stopper portion (μm) | | | | portion (%) | |
| | Bi | Ag | Cu | Sn | Bi | Ag | Cu | Sn | tion | mounting | Ave. | Max. | Min. | Ave. | Max. | Min. | Variation | Bi | Ag3Sn |
| Thir- | 58.0 | 0.0 | 0.0 | 42.0 | 48.1 | 0.5 | 0.1 | 51.3 | 240 | 240 | 2.3 | 4.2 | 0.0 | 3.6 | 4.2 | 3.2 | +17%/−11% | 52 | 20 |
| teenth | | | | | | | | | | | | | | | | | | | |
| embodi- | | | | | | | | | | | | | | | | | | | |
| ment | | | | | | | | | | | | | | | | | | | |
| Four- | 58.0 | 0.0 | 0.0 | 42.0 | 48.1 | 0.5 | 0.1 | 51.3 | 240 | 260 | 3.5 | 5.5 | 2.0 | 4.0 | 5.0 | 3.6 | +25%/−10% | 39 | 29 |
| teenth | | | | | | | | | | | | | | | | | | | |
| embodi- | | | | | | | | | | | | | | | | | | | |
| ment | | | | | | | | | | | | | | | | | | | |

As understood from the result of Table 5, when the peak temperature at reflow at the time of formation of each terminal and connection of the substrate is set to 240° C., the thickness of each intermetallic compound excepting the stopper portion is suppressed. Further, a variation thereof is also small and the proportion of each stopper portion has increased as well.

While the preferred forms of the present invention have been described, it is to be understood that modifications will be apparent to those skilled in the art without departing from the spirit of the invention. The scope of the invention is to be determined solely by the following claims.

1. A semiconductor device comprising:
external connecting terminals,
wherein said each external connecting terminal includes:
a Cu electrode,
intermetallic compounds containing Cu, each formed over the Cu electrode,
stopper portions which cover surfaces of the intermetallic compounds at intervals, and
a solder alloy comprising Bi and an impurity containing Sn formed over the stopper portions and the intermetallic compounds.

2. The semiconductor device according to claim 1, wherein the solder alloy is formed of solder in which a composition ratio of said Bi ranges from 32 wt % or more to 75 wt % or less.

3. The semiconductor device according to claim 1, wherein the solder alloy contains Ag.

4. The semiconductor device according to claim 1, wherein the stopper portion comprises an element having a positive enthalpy of mixing at the time that the same is mixed into Cu or the respective intermetallic compounds, or the element and a compound.

5. The semiconductor device according to claim 1, wherein the stopper portion comprises Bi or Bi and Ag3Sn.

6. The semiconductor device according to claim 2, wherein the solder alloy contains Ag.

7. The semiconductor device according to claim 2, wherein the stopper portion comprises an element having a positive enthalpy of mixing at the time that the same is mixed into Cu or the respective intermetallic compounds, or the element and a compound.

8. The semiconductor device according to claim 3, wherein the stopper portion comprises an element having a positive enthalpy of mixing at the time that the same is mixed into Cu or the respective intermetallic compounds, or the element and a compound.

9. The semiconductor device according to claim 2, wherein the stopper portion comprises Bi or Bi and Ag3Sn.

10. The semiconductor device according to claim 3, wherein the stopper portion comprises Bi or Bi and Ag3Sn.

11. The semiconductor device according to claim 4, wherein the stopper portion comprises Bi or Bi and Ag3Sn.
